(19) United States
(12) Patent Application Publication
(10) Pub. No.: US 2025/0277840 A1
(43) Pub. Date: Sep. 4, 2025

(54) CAPACITOR HEALTH DIAGNOSIS SYSTEM AND METHOD

(71) Applicant: HITACHI ENERGY USA INC., Raleigh, NC (US)

(72) Inventors: HyoJong LEE, Raleigh, NC (US); Reynaldo NUQUI, Cary, NC (US)

(21) Appl. No.: 18/859,493

(22) PCT Filed: May 5, 2022
(86) PCT No.: PCT/US2022/027904

§ 371 Date: Oct. 23, 2024

(51) Int. Cl. G01R 31/01; G01R 19/00; G01R 23/165; G01R 27/26

(52) U.S. Cl. CPC G01R 31/016; G01R 19/0007; G01R 23/165; G01R 27/2605

(57) ABSTRACT

In an embodiment, an electronic circuit includes: one or more input terminals configured to receive measurement data; and a controller configured to: determine a first harmonic current based on a first current flowing through a first circuit coupled to a line node, where the measurement data includes first current data indicative of the first current, determine a filter harmonic current based on a filter current flowing through an AC filter coupled to the line node, where the measurement data includes filter current data indicative of the filter current, and generate a first flag indicative of failure, degradation or malfunction of a first capacitor or capacitor bank based on the first harmonic current and the filter harmonic current, where the AC filter includes the first capacitor or capacitor bank.

### GOVERNMENT LICENSE RIGHTS

This invention was made with government support under contract number DE-OE0000897 awarded by the U.S. Department of Energy. The government has certain rights in the invention.

### TECHNICAL FIELD

The present disclosure relates generally to an electronic system and method, and, in particular embodiments, to a capacitor health diagnosis system and method.

### BACKGROUND

A flexible alternating current transmission system (FACTS) may be understood as a system that includes equipment for the alternating current (AC) transmission of electrical energy. Generally, FACTS includes a static volt-ampere reactive (VAR) compensator (SVC) or a static synchronous compensator (STATCOM), also known as a static synchronous condenser (STATCON), to provide reactive power to the network, e.g., to regulate voltage, power factor, harmonics, and/or stabilize the network.

FIG. 1 shows a schematic diagram of exemplary SVC 100, e.g., for a three-phase system. SVC 100 includes thyristor-switched capacitor (TSC) circuit 102, thyristor-controlled reactor (TCR) circuit 104, and AC filter 106. AC filter 106 includes capacitor or capacitor bank 116. TSC circuit 102 includes capacitor or capacitor bank 118.

As shown, TSC circuit 102 is delta connected with the other phases in a known manner. TCR circuit 104 is also delta connected with the other phases in a known manner. AC filter 106 may be implemented with a Y connection.

As shown in FIG. 1, transformer 103 may be used to step-down the voltage from the voltage of AC grid 101 to a lower voltage. For example, the voltage V_{grid} may be between 1 kV and 800 kV, such as 230 kV, and the voltage Vₗᵢₙₑ may be equal to or lower than 21.4 kV.

TCR circuit 104 and SVC circuit 102 may be used to continuously adjust the reactive power delivered to AC grid 101 by the controlled switching of thyristor valves 108, 110, 112, and 114. During this switching in the TCR circuit 104, undesired current harmonics may be generated. For example, the switching of the thyristor valves in TCR circuit 104 may draw non-sinusoidal current, which may cause harmonic distortion in the FACTS station. In general, the lower harmonic (e.g., 3rd harmonics) may be trapped by the delta connection of TCR circuit 104. However, higher harmonics may still appear and may be injected into AC grid 101. Such harmonics may be harmful to AC grid 101. AC filter 106 may be used to prevent the injection of harmonics into AC grid 101, e.g., generated by TCR circuit 104.

Although a single AC filter 106 is shown in FIG. 1, an AC filter 106 for each harmonic to be suppressed may be used. For example, if suppression of the 5^{th}, 7^{th}, and 13^{th} harmonics of the fundamental frequency (e.g., 50 Hz or 60 Hz) is desired, then 3 AC filters 106 respectively tuned to the 5^{th}, 7^{th}, and 13^{th} harmonics, may be coupled, in parallel, to the Vₗᵢₙₑ node.

FIG. 2 shows a schematic diagram of exemplary STATCOM 200, e.g., for a three-phase system. STATCOM 200 includes voltage-source converter (VSC) 204 and AC filter 202. AC filter 202 includes capacitor or capacitor bank 206.

VSC 204 may be operated with pulse-width modulation (PWM), e.g., with millisecond switching, e.g., to adjust the reactive power delivered to AC grid 101. VSC 204 may generate harmonic distortion (e.g., similar to TSC 102). For example, although, by design, the phase shifted PWM based VSC 204 may cancel harmonics up to the 2·f_{cr}·N harmonics in voltage (where f_{cr} represents the carrier frequency of the PWM and N represents the total number of cells in each phase), higher frequency harmonics may still appear in the voltage Vₗᵢₙₑ. Distortion in voltage Vₗᵢₙₑ due to harmonics in AC current may cause unwanted effects in power systems (e.g., synchronous/induction machine failure, higher power loss, or excessive heating in AC equipment). AC filter 202 may be used to reduce the harmonics of the fundamental frequency (e.g., 50 Hz or 60 Hz) generated by the PWM switching of VSC 204 (e.g., by providing better power factor), and/or to provide reactive power as fixed shunt capacitors.

FIG. 3 shows a schematic diagram of exemplary high-voltage direct current (HVDC) electric power transmission system 300 (also referred to as a power superhighway or an electrical superhighway). HVDC system 300 includes HVDC converter 301, harmonic filters 302 and 304, and high pass AC filter 306. AC filter 302 includes capacitor or capacitor bank 308. AC filter 304 includes capacitor or capacitor bank 310. AC filter 306 includes capacitor or capacitor bank 312. During generation of power by HVDC converter 301, harmonics may be generated, which may be reduced by AC filters 302, 304, and 306 to prevent injection of such harmonics into AC grid 101. AC filter 302 may be designed to suppress the 11^{th} harmonic of the fundamental frequency (e.g., 50 Hz or 60 Hz). AC filter 304 may be designed to suppress the 13^{th} harmonic of the fundamental frequency (e.g., 50 Hz or 60 Hz). High pass AC filter 306 may have a corner frequency of 24^{th} to more of the fundamental frequency.

Systems 100, 200, and 300, are exemplary, and the target harmonics to be suppressed by AC filters 106, 202, 302, 304, and/or 306 may be different (e.g., depending on the design of the system).

As shown in FIGS. 1-3, capacitors or capacitor banks 116, 206, 308, 310, and 312 in FACTS may help filter out unwanted harmonics and limit the harmonics that enter AC grid 101 as well as compensate for voltage dig/sag in the AC system.

Capacitors may fail or degrade with time. For example, process variations may cause capacitors to degrade or fail at different times/rates. Capacitor manufacturers generally provide capacitor failure models, which generally have a large variance and show a low confidence level.

Environmental factors may also affect the life of a capacitor. For example, when a capacitor is exposed to conditions outside the rated conditions for the capacitor (such as outside the operational voltage/temperature/frequency), the capacitor may degrade or fail faster than anticipated.

Failures or degradation of a capacitor may affect the operation of AC filters 106, 202, 302, 304, and 306, and TSC circuit 102. For example, the ability of AC filters 106, 202, 302, 304, and 306 to filter desired frequencies may degrade as the capacitance of capacitors or capacitor banks 116, 206, 308, 310, and 312 changes. As another example, in capacitive H-bridges, such as shown in FIG. 1 for TSC circuit 102, capacitor failure or degradation (e.g., a shift in capacitance) may cause an unbalance in the H-bridge.

To ensure proper operation of AC filters 106, 202, 302, 304, and 306, TSC circuit 102, capacitors or capacitor banks 116, 118, 206, 308, 310, and 312 may be monitored by taking the associated circuits offline and performing capacitance testing on the capacitors.

### SUMMARY

In accordance with an embodiment, an electronic circuit includes: one or more input terminals configured to receive measurement data; and a controller configured to: determine a first harmonic current based on a first current flowing through a first circuit coupled to a line node, where the measurement data includes first current data indicative of the first current, determine a filter harmonic current based on a filter current flowing through an AC filter coupled to the line node, where the measurement data includes filter current data indicative of the filter current, and generate a first flag indicative of failure, degradation or malfunction of a first capacitor or capacitor bank based on the first harmonic current and the filter harmonic current, where the AC filter includes the first capacitor or capacitor bank.

In accordance with an embodiment, a method includes: determining a first harmonic current based on a first current flowing through a first circuit coupled to a line node; determining a filter harmonic current based on a filter current flowing through an AC filter coupled to the line node; and generating a first flag indicative of failure, degradation or malfunction of a first capacitor or capacitor bank based on the first harmonic current and the filter harmonic current, where the AC filter includes the first capacitor or capacitor bank.

In accordance with an embodiment, a device includes: one or more input terminals configured to receive measurement data; and a controller configured to: determine M capacitance values of a first capacitor or capacitor bank of an AC filter coupled to a line node based on the measurement data, where M is a positive integer greater than 1, associate each of the M determined capacitance values to a cluster of k clusters, where k is a positive integer greater than 1 and smaller than M, determine a dominant cluster from the k clusters, determine a first capacitance based on the capacitance values of the dominant cluster, compare the first capacitance with a reference capacitance, and generate a first flag when the first capacitance differs from the reference capacitance by more than a predetermined tolerance, where the first flag is indicative of a failure, degradation, or malfunction of the first capacitor or capacitor bank.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 shows a schematic diagram of an exemplary SVC;

FIG. 2 shows a schematic diagram of an exemplary STATCOM;

FIG. 3 shows a schematic diagram of an exemplary high-voltage direct current (HVDC) electric power transmission system;

FIG. 4 shows a schematic diagram of an SVC, according to an embodiment of the present disclosure;

FIG. 5 shows a flow chart of embodiment a method for determining the health of a capacitor or capacitor bank, according to an embodiment of the present disclosure;

FIG. 6 shows a flow chart of an embodiment method for determining the health of a plurality of capacitors or capacitor banks, according to an embodiment of the present disclosure;

FIGS. 7A and 7B show exemplary AC filters;

FIG. 8 shows a flow chart of an embodiment method for monitoring the health of a capacitor or capacitor bank, according to an embodiment of the present disclosure;

FIG. 9 shows a flow chart of an embodiment method for monitoring the health of a capacitor or capacitor bank, according to an embodiment of the present disclosure;

FIG. 10 shows a flow chart of an embodiment method for determining a capacitance of a capacitor or capacitor bank, according to an embodiment of the present disclosure;

FIG. 11 shows a flow chart of an embodiment method for monitoring the health of a capacitor or capacitor bank, according to an embodiment of the present disclosure;

FIG. 12 shows a schematic diagram of a STATCOM, according to an embodiment of the present disclosure; and

FIG. 13 shows a schematic diagram of an HVDC system, according to an embodiment of the present disclosure; and

FIG. 14 shows a schematic diagram of a device, according to an embodiment of the present disclosure.

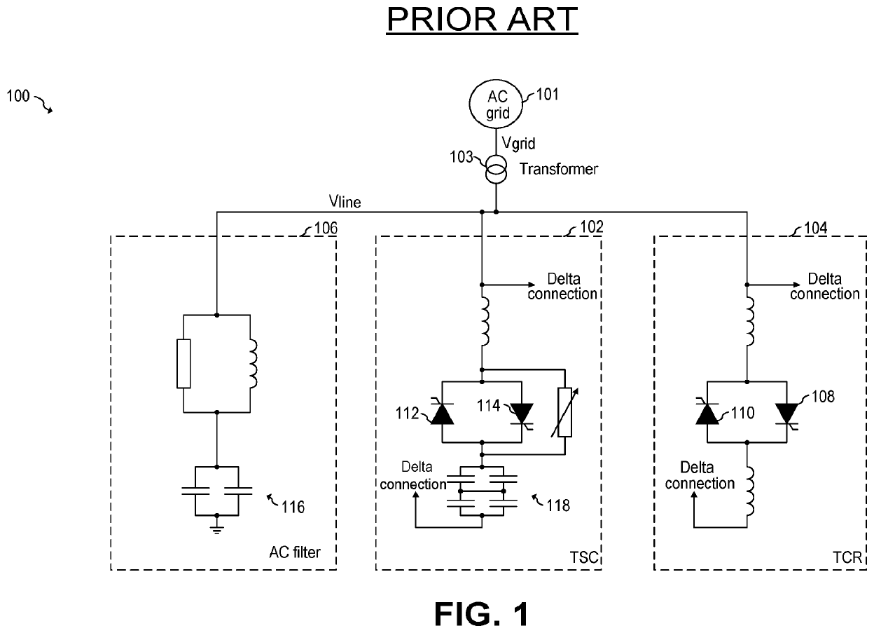

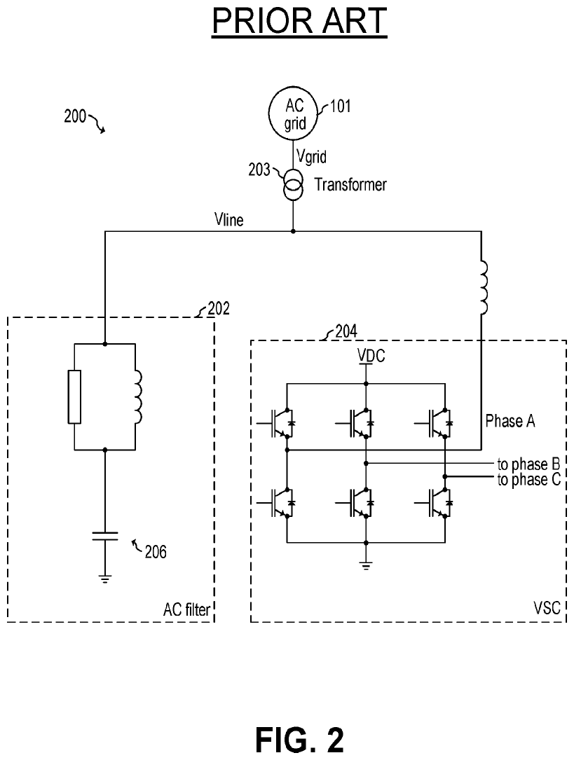

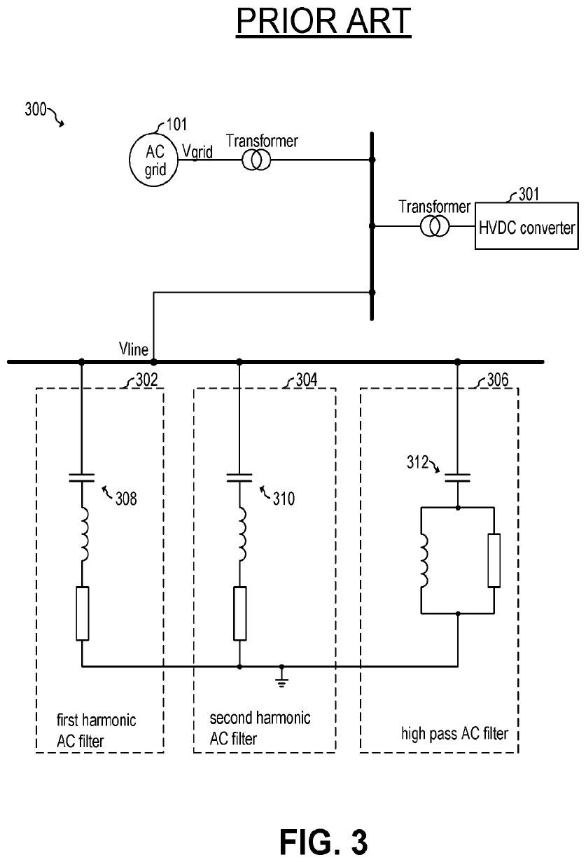

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the invention, and do not limit the scope of the invention.

The description below illustrates the various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Embodiments of the present disclosure will be described in specific contexts, e.g., a power system capacitor health diagnosis in FACTS. Embodiments of the present disclosure may be used in other applications, such as in power systems different from FACTS (e.g., shunt capacitor, HVDC), as well as in other circuits that may benefit from capacitor health monitoring.

In an embodiment of the present disclosure, a health of capacitor banks in a FACTS device is diagnosed in real time based on the (e.g., instantaneous) voltage and harmonic current signals of the AC grid and the voltage and harmonic current signals of the FACTS device. In some embodiments, when a capacitor failure, degradation or malfunction is detected, the harmonic current signals may advantageously be used to identify the failed capacitor bank. In some embodiments, the capacitance of the capacitor bank may be determined, and deviations in capacitance may be used to detect failure, degradation or malfunction of the capacitor bank. In some embodiments, the capacitance is determined using a k-means algorithm. In some embodiments, the capacitance trend may be used to detect degradation of the capacitor bank due to aging. In some embodiments, the capacitance trend may be used to detect a possible cyber intrusion. In some embodiments, the capacitance trend may be determined using a linear regression algorithm.

Advantages of some embodiments include the ability to monitor the health of capacitor banks in FACTS devices without shutting down the AC switchyard. In some embodiments, such online approach of capacitor health monitoring advantageously enables timely detection of incipient capacitor failure and avoids costly maintenance or unscheduled forced outages of the capacitor banks in the FACTS devices.

Some embodiments may advantageously be implemented without adding any additional hardware to an existing FACTS device.

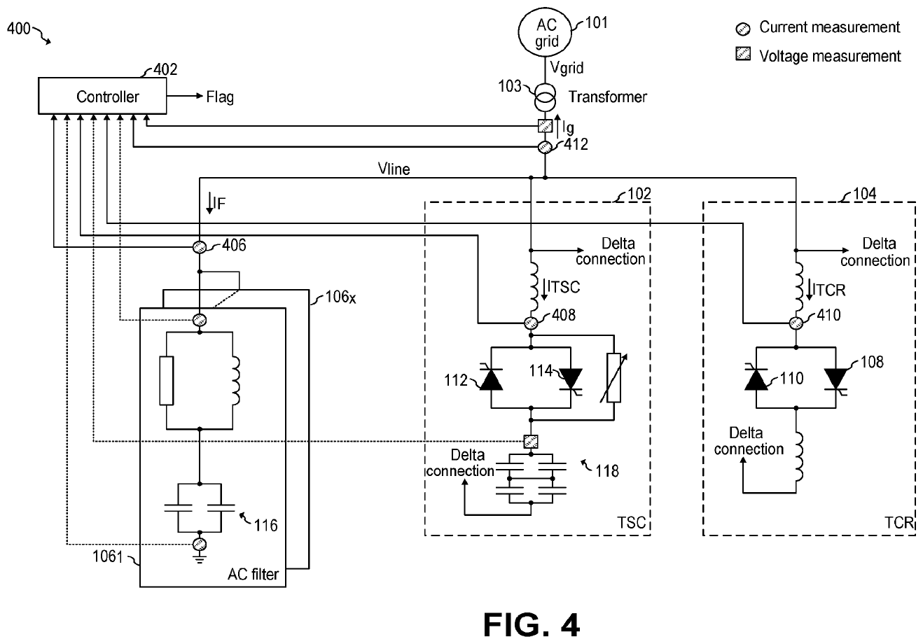

FIG. 4 shows a schematic diagram of SVC 400, according to an embodiment of the present disclosure. SCV 400 operates in a similar manner as SVC 100, and includes x AC filters 106, where x is a positive integer greater than or equal to 1. SVC 400, however, includes controller 402.

In some embodiments, current measurement circuits 406, 408, 410, and/or 412 may be implemented in any way known in the art. For example, in some embodiments, current may be sampled by the current measurement circuits (e.g., 406, 408, 410, and/or 412) using an analog-to-digital converter (ADC) at a frequency above the mains frequency, such as at 1 KHz, 1.2 kHz, or higher. Other sampling frequencies may also be used.

As shown in FIG. 4, in some embodiments, a single measurement circuit 406 may be shared across a plurality of AC filter 106. As also shown in FIG. 4, in some embodiments, a respective current measurement circuit may be used for each AC filter 106.

In some embodiments, controller 402 includes one or more input terminals configured to receive data from current measurement circuits (e.g., 406, 408, 410, and 412) and perform further processing based on the received data. In some embodiments, controller 402 may be implemented as a custom or generic controller or processor, e.g., coupled to a memory and configured to execute instructions stored in the memory. In some embodiments, controller 402 is part of an intelligent electronic device (IED), such as an integrated microprocessor-based controller of power system equipment. In some embodiments, controller 402 is part of a server (e.g., a substation computer with I/O) that communicates with an IED, where the IED receives the current and voltage measurements (e.g., I_{F}, I_{g}, I_{TCR}, Vₗᵢₙₑ, etc.) and transmits such measurements to the server.

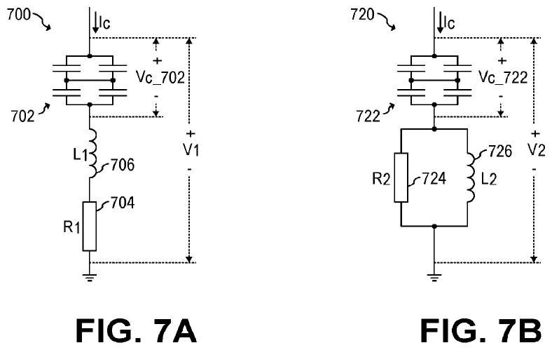

In some embodiments, each of the x AC filters 106 is designed to filter a respective harmonic. For example, in some embodiments, x is equal to 3, and the 3 AC filters 106 are designed to filter the 5^{th} 7^{th} and 13^{th} harmonic of the fundamental frequency (e.g., 50 Hz or 60 Hz), respectively. In some embodiments, one or more (or all) of AC filters 106 may be implemented with the topology shown in FIG. 4. In some embodiments, one or more (or all) of AC filters 106 may be implemented with a different topology. In some embodiments, one or more (or all) of AC filters 106 may be implemented as high pass filter or band pass filter. In some embodiments, one or more (or all) of AC filters 106 may be implemented as a double tuned filter. In some embodiments, one or more (or all) of AC filters 106 may be implemented as a shunt capacitor. In some embodiments, one or more (or all) of AC filters 106 may be implemented as AC filters 700 or 720 (shown in FIGS. 7A and 7B, respectively). Other implementations are also possible. According to Kirchhoff's current law (KCL), in some embodiments, the relationship between currents I_{g}, I_{TSC}, I_{TCR} and I_{F} may be given by

$${I}_{g} + {I}_{TSC} + {I}_{TCR} + {I}_{F} = 0 , \qquad ( 1 )$$

where I_{g} represents the current going into AC grid 101, I_{F} represents the current going into AC filter 106, I_{TSC} represents the current going into TSC circuit 102, and I_{TCR} represents the current going into TCR circuit 104.

Harmonic currents may also be analyzed according to KCL. Thus, in some embodiments, the relationship between harmonic currents I_{g}ⁿ^{^{th}}, I_{TSC}ⁿ^{^{th}}, I_{TCR}ⁿ^{^{th}}, and I_{F}ⁿ^{^{th}} may be given by

$${I}_{g}^{{n}^{th}} + {I}_{TSC}^{{n}^{th}} + {I}_{TCR}^{{n}^{th}} + {I}_{F}^{{n}^{th}} = 0 , \qquad ( 2 )$$

where I_{g}ⁿ^{^{th}} represents the n^{th} harmonic current going into AC grid 101, I_{F}ⁿ^{^{th}} represents the n^{th} harmonic current going into AC filter 106, I_{TSC}ⁿ^{^{th}} represents the n^{th} harmonic current going into TSC circuit 102, and I_{TCR}ⁿ^{^{th}} represents the n^{th} harmonic current going into TCR circuit 104.

In some embodiments, the n^{th} harmonic current may be determined by measuring the current (e.g., I_{F}, I_{TSC}, I_{TCR} and I_{g}, e.g., in a known manner), performing a Fourier transform (e.g., a discrete Fourier transform (DFT)) on the measured current to generate a frequency spectrum, and determine the energy of the frequency corresponding to the n^{th} harmonic in the generated frequency spectrum.

In some embodiments, n is equal to 5, 7, or 13. In some embodiments, n may be a different number, such as a different odd number.

In some embodiments (as shown in FIG. 4), multiple AC filters 106 are used to filter various harmonics. For example, in some embodiments, 3 AC filters 106 are connected to the Vₗᵢₙₑ node to filter the 5^{th}, 7^{th}, and 13^{th} harmonics, respectively. Less than 3 AC filters 106, or more than 3 AC filters 106 may also be used.

Since, in some embodiments, TSC circuit 102 generates negligible harmonic currents, Equation 2 may be simplified as

$${I}_{g}^{{n}^{th}} + {I}_{TCR}^{{n}^{th}} + {I}_{F}^{{n}^{th}} = 0. \qquad ( 3 )$$

It can be inferred from Equation 3 that, for the n^{th} harmonic current I_{g}ⁿ^{^{th}} going into AC grid 101 to be zero, or close to zero, then

$${I}_{F}^{{n}^{th}} ≅ - {I}_{TCR}^{{n}^{th}} . \qquad ( 4 )$$

In some embodiments, when the magnitude of the harmonic current I_{F}ⁿ^{^{th}} is close to the magnitude of the harmonic current I_{TCR}ⁿ^{^{th}} (e.g., when the magnitude of harmonic current I_{F}ⁿ^{^{th}} is within 5% of the magnitude of harmonic current I_{TCR}ⁿ^{^{th}}), the capacitor or capacitor bank 116 is determined to be operating properly. When the magnitude of the harmonic current I_{F}ⁿ^{^{th}} is not close to the magnitude of the harmonic current I_{TCR}ⁿ^{^{th}} (e.g., when the magnitude of harmonic current I_{F}ⁿ^{^{th}} is not within 5% of the magnitude of harmonic current I_{TCR}ⁿ^{^{th}}), the capacitor or capacitor bank 116 of the filter designed to filter the n^{th} harmonic is flagged, e.g., for maintenance (e.g., monitoring and/or replacement), and/or for performing further testing on capacitor or capacitor bank 116.

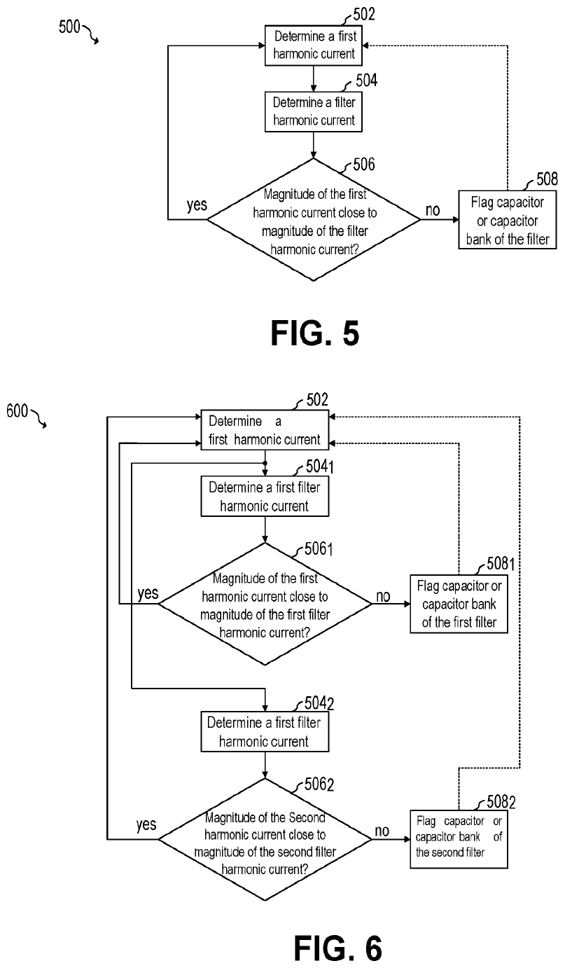

FIG. 5 shows a flow chart of embodiment method 500 for determining the health of a capacitor or capacitor bank, according to an embodiment of the present disclosure. Method 500 may be implemented by, e.g., controller 402.

During step 502, a first harmonic current (e.g., I_{TCR}ⁿ^{^{th}}) is determined. For example, in some embodiments, a first current (e.g., I_{TCR}) flowing through a first circuit (e.g., 104) is measured, and a DFT is performed on the measured first current to generate a frequency spectrum, where the magnitude of the first harmonic current (e.g., I_{TCR}ⁿ^{^{th}}) corresponds to the magnitude of the frequency spectrum at the harmonic frequency. In some embodiments, the first current (e.g., I_{TCR}) is measured in a known manner (e.g., by current measurement circuit 410). In some embodiments, the DFT is performed by a controller (e.g., 402).

During step 504, a filter harmonic current (e.g., I_{F}ⁿ^{^{th}}) is determined. For example, in some embodiments, a filter current (e.g., I_{F}) is measured, and a DFT is performed on the measured filter current to generate a frequency spectrum, where the magnitude of the filter harmonic current (e.g., I_{TCR}ⁿ^{^{th}}) corresponds to the magnitude of the frequency spectrum at the harmonic frequency. In some embodiments, the filter current (e.g., I_{F}) is measured in a known manner (e.g., by current measurement circuit 406). In some embodiments, the DFT is performed by a controller (e.g., 402).

During step 506, the magnitude of the first harmonic current (e.g., I_{TCR}ⁿ^{^{th}}) is compared with the magnitude of the filter harmonic current (e.g., I_{F}ⁿ^{^{th}}). In some embodiments, if the magnitude of the first harmonic current (e.g., I_{TCR}ⁿ^{^{th}}) is not close to the magnitude of the filter harmonic current (e.g., I_{F}ⁿ^{^{th}}), then step 508 is performed. In some embodiments, during step 506, if it is determined that

$$\frac{{I}_{F}^{{n}^{t h}} - {I}_{TCR}^{{n}^{t h}}}{{I}_{TCR}^{{n}^{t h}}} < {I}_{thres}^{{n}^{t h}} . \qquad ( 5 )$$

where Iₜₕᵣₑₛⁿ^{^{th}} represents a threshold for the n^{th} harmonic, then step 508 is performed.

In some embodiments, threshold Iₜₕᵣₑₛⁿ^{^{th}} may be equal to a percentage higher than 90%, such as 95%. Other values, such as a presentence higher than 95% or a percentage lower than 90%, may also be used.

In some embodiments, all thresholds Iₜₕᵣₑₛⁿ^{^{th}} (for all harmonics) are equal to each other. In some embodiments, one or more (or all) of thresholds Iₜₕᵣₑₛⁿ^{^{th}} may be different.

During step 508, a flag is generated (e.g., by controller 402). In some embodiments, the flag is indicative of failure, degradation or malfunction of the capacitor or capacitor bank (e.g., 116). For example, in some embodiments, the capacitor or capacitor bank (e.g., 116) of the AC filter 106 associated with the n^{th} harmonic is flagged, e.g., for maintenance, replacement, or further monitoring. For example, in some embodiments, the controller (e.g., 402) may cause an operator to be notified (e.g., via email, message, sound, at an operator terminal, etc.) that a deviation in performance of the capacitor or capacitor bank (e.g., 116) has been detected and, e.g., requires attention. As another example, in some embodiments, the controller (e.g., 402) may cause further testing to be performed on the capacitor or capacitor bank (e.g., 116). In some embodiments, the step of generating the flag includes identifying the failed, degraded or malfunctioned capacitor or capacitor bank (e.g., the capacitor or capacitor bank of the AC filter designed to filter the harmonic current compared during step 506 that cause the output of step 506 to be “no”).

In some embodiments, performing steps 502, 504, 506, and 508 advantageously allows for identification of a failed, degraded or malfunctioned capacitor or capacitor bank without shutting down the AC switchyard to perform the diagnosis of the capacitor or capacitor bank.

As illustrated in FIG. 5, steps 502, 504, and 506 may be performed, e.g., periodically, until the output of step 506 becomes “no.” In some embodiments, steps 502, 504, and 506 may continue to be performed after step 508 is performed. In some embodiments, steps 502, 506, and 506, may be performed on demand.

Advantages of some embodiments include the ability to monitor the health of a capacitor or capacitor bank (e.g., in a FACTS device) in real time and without shutting down the AC switchyard to perform the diagnosis of the capacitor or capacitor bank. In some embodiments, monitoring the health of a capacitor or capacitor bank in real time advantageously allows for timely detection of capacitor failure, and advantageously avoids delaying maintenance of the FACTS or AC filter(s).

In some embodiments, method 500 may be performed (e.g., simultaneously or sequentially) to monitor the health of capacitors or capacitor banks of a plurality of filters (e.g., of a plurality of AC filters 106). For example, FIG. 6 shows a flow chart of embodiment method 600 for determining the health of a plurality of capacitors or capacitor banks, according to an embodiment of the present disclosure. Method 600 may be implemented by, e.g., controller 402.

Method 600 is similar to method 500. Method 600, however, monitors the health of a plurality of capacitors or capacitor banks associated with a respective plurality of AC filters (e.g., 116). For example, as shown in FIG. 6, method 600 may be used to monitor the health of 2 AC filters 116, where steps 504₁, 506₁, and 508₁ are performed in connection with monitoring the health of a first capacitor or capacitor bank 116 (associated with AC filter 106₁), and steps 504₂, 506₂, and 508₂ are performed in connection with monitoring the health of a second capacitor or capacitor bank (associated with AC filter 106₂).

Step 502 may be performed in a similar manner as described with respect to method 500. Each of steps 504₁ and 504₂ may be performed in a similar manner as step 504. Each of steps 506₁ and 506₂ may be performed in a similar manner as step 506. Each of steps 508₁ and 508₂ may be performed in a similar manner as step 508.

As a non-limiting example, in some embodiments (e.g., as illustrated in FIG. 6), method 600 may be used to monitor the health of 2 AC filters 106 for filtering respective harmonics (e.g., 5^{th}, and 7^{th} harmonics). In some embodiments, method 600 may be extended to monitor more than 2 AC filters 116, such as 3 or more (e.g., by performing additional steps 504ᵢ, 506ᵢ, and 508ᵢ, where i is a number from 3 to x, where x represents the number of AC filters 106).

As shown in FIG. 6, some embodiments are advantageously capable of detecting in real time a deviation in performance of a capacitor or capacitor bank and its associated location. For example, in an embodiment in which the first and second AC filters 116 are designed to filter the 5^{th} and 7^{th} harmonics, respectively, when step 506₁ outputs “no,” the location of the capacitor or capacitor bank 116 associated with the detected deviation corresponds to the location of the capacitor or capacitor bank of the AC filter 106 designed for filtering the 5^{th} harmonic. When step 506₂ outputs “no,” the location of the capacitor or capacitor bank 116 associated with the detected deviation corresponds to the location of the capacitor or capacitor bank of the AC filter 106 designed for filtering the 7^{th} harmonic.

In some embodiments, in response to a capacitor or capacitor bank being flagged during step 508, the capacitance of such capacitors or capacitor bank is determined (e.g., using method 800, described below), e.g., to determine whether the capacitance is within the expected tolerance or if the capacitor or capacitor bank should be replaced, e.g., immediately. In some embodiments, the capacitance C_{det} of a capacitor or capacitor bank may be determined by

$${C}_{det} = {I}_{c} \cdot \frac{Δ {V}_{c}}{Δ t} . \qquad ( 6 )$$

where I_{c} represents the current going into or out of the capacitor or capacitor bank, V_{c} represents the voltage across the capacitor or capacitor bank, ΔV_{c} represents the difference in voltage between two samples of voltage V_{c}, and Δt represents the time between voltage samples.

In some embodiments, current I_{c} corresponds to a single current measurement. In some embodiments, current I_{c} corresponds to the average of a plurality of current measurements (e.g., taken during the period of time Δt). In some embodiments, using a plurality of current measurements may advantageously increase the accuracy of the determined capacitance C_{det}.

In some embodiments, a plurality of capacitances C_{det} may be determined and averaged to determine the capacitance of the capacitor or capacitor bank. In some embodiments, averaging a plurality of capacitances C_{det} to determine the capacitance of the capacitor or capacitor bank may advantageously increase the accuracy of the determined capacitance C_{det}.

In some embodiments, the sampling rate of voltage V_{c} may be higher than the mains frequency, such as 1 kHz, 1.2 kHz, or higher. Other frequencies may also be used.

In some embodiments, current I_{c} is measured directly. For example, in some embodiments, current I_{c} corresponds to current I_{F}, and may be measured, e.g., with current measurement circuit 406.

In some embodiments, methods 500 and 600 may be performed periodically. In some embodiments, methods 500 and 600 may be performed on demand. In some embodiments, methods 500 and 600 may be performed continuously.

In some embodiments, voltage V_{c} may be measured directly. In some embodiments, voltage V_{c} may be determined based on current I_{c} and a voltage of the AC filter. For example, FIG. 7A shows exemplary high pass filter 700 (also referred to as a single tune circuit). In some embodiments, voltage V_{c_702} across capacitor bank 702 may be determined by

$${V}_{c \_ 702} = {V}_{1} - {I}_{c \_ 702} \cdot {R}_{1} - {L}_{1} \cdot \frac{Δ {I}_{c}}{Δ t} . \qquad ( 7 )$$

where V₁ represents the voltage across AC filter 700, current I_{c_702} represents the current flowing through AC filter 700, R₁ represents the resistance of resistor 704, L₁ represents the inductance of inductor 706, ΔI_{c} represents the difference in current between two samples of current I_{c}, and Δt represents the time between current samples. In some embodiments, voltage V_{c_702} and current I_{c_702} may be used with Equation 6 to determine the capacitance C_{det_702} of capacitor bank 702.

In some embodiments, R₁ and L₁ are known values, and current I_{c_702} and voltage V₁ are measured directly. In some embodiments, the sampling rate of voltage V₁ may be higher than the mains frequency, such as 1 kHz, 1.2 kHz, or higher. Other frequencies may also be used. In some embodiments, voltage V₁ may correspond to voltage Vₗᵢₙₑ.

FIG. 7B shows exemplary high pass filter 720. In some embodiments, voltage V_{c_722} across capacitor bank 702 may be determined by

$${V}_{c \_ 722} = {V}_{2} - {I}_{c \_ 722} \cdot ( {R}_{2} \vert \vert {L}_{2} ) . \qquad ( 8 )$$

where V₂ represents the voltage across AC filter 720, current I_{c_722} represents the current flowing through AC filter 720, R₂ represents the resistance of resistor 724, L₂ represents the inductance of inductor 726, and ∥ is the parallel connection symbol. In some embodiments, voltage V_{c_722} and current I_{c_722} may be used with Equation 6 to determine the capacitance C_{det_722} of capacitor bank 722.

In some embodiments, R₂ and L₂ are known values, and current I_{c_722} and voltage V₁ are measured directly. In some embodiments, the sampling rate of voltage V₁ may be higher than the mains frequency, such as 1 kHz, 1.2 kHz, or higher. Other frequencies may also be used. In some embodiments, voltage V₁ may correspond to voltage Vₗᵢₙₑ. As shown in FIG. 4, in some embodiments, voltage Vₗᵢₙₑ may be measured directly.

It is understood that Equations 7 and 8 may be modified based on the topology of the AC filter.

In some embodiments, the capacitance of a capacitor or capacitor bank may be determined using Equation 6. In some embodiments, the capacitance of a capacitor or capacitor bank may be determined in other ways (e.g., depending on the signal condition of the system) For example, in some embodiments, the capacitance of a capacitor or capacitor bank may be determined using

$${C}_{det} = \frac{1}{{V}_{tf} - {V}_{ti}} \cdot {\int }_{ti}^{tf} {I}_{c} dt . \qquad ( 9 )$$

where V_{tf} and Vₜᵢ represent voltages across the capacitor or capacitor bank measured at times tf and ti, respectively.

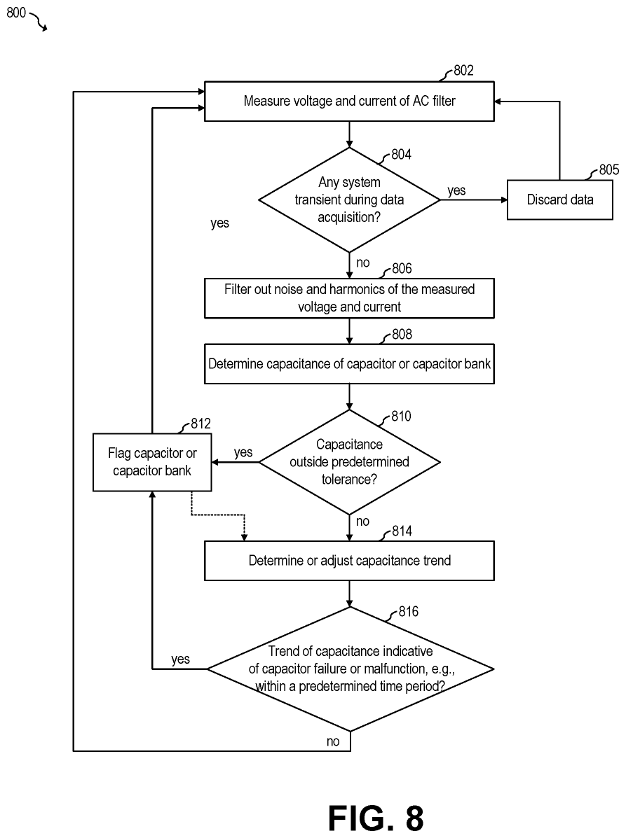

In some embodiments, the capacitance C_{det} may be determined, e.g., periodically, e.g., to detect when the capacitance C_{det} fall outside an acceptable range (e.g., outside +/−5% the target capacitance value). In some embodiments, the trend of capacitance C_{det} may be determined, e.g., to determine a probable time of failure. In some embodiments, if the probable time of failure is within a predetermined threshold (e.g., within 3 month), the capacitor or capacitor bank associated with the capacitance trend is flagged, e.g., for replacement. For example, FIG. 8 shows a flow chart of embodiment method 800 for monitoring the health of a capacitor or capacitor bank, according to an embodiment of the present disclosure. Method 800 includes steps 802, 804, 806, 808, 810, 812, 814, and 816. Method 800 may be implemented by, e.g., controller 402.

During step 802, a voltage (e.g., Vₗᵢₙₑ) of an AC filter (e.g., 106) and a current (e.g., I_{F}) of the AC filter are measured (e.g., using voltage and current measurement circuits, e.g., as shown in FIG. 4). For example, in some embodiments, the voltage (e.g., Vₗᵢₙₑ) and current (e.g., I_{F}) of the AC filter (e.g., 106) are measured periodically in a known manner. For example, in some embodiments, the voltage and current of the AC filter are sampled (e.g., at a sampling rate of 1 kHz or higher, such as at 1.2 kHz) during a predetermined time window. In some embodiments, the predetermined time window is 10 seconds. Longer time windows (e.g., 15 seconds, 20 second, or longer), or shorter time windows (e.g., 8 seconds or shorter) may also be used.

During step 804, it is determined whether there any transient events occurred during the performance of step 802 (during the predetermined time window). Transient events may include changes in the voltage setpoint of AC grid 101, for example. If it is determined during step 804 that a transient event occurred during data acquisition, the measurements collected during step 802 are discarded during step 805. If there are no detected transient events, step 806 is performed.

During step 806, the voltage and current data collected during step 802 are filtered to remove noise and harmonic content, e.g., keeping the data associated with the fundamental frequency (e.g., 50 Hz or 60 Hz). In some embodiments, the filters used during step 806 may be FIR filters. In some embodiments, the voltage and current data may be filtered in other ways known in the art.

During step 808, the capacitance of the capacitor or capacitor bank (e.g., 116) is determined, e.g., using one or more of Equations 6-9. If it is determined during step 810 that the capacitance of the capacitor or capacitor bank is outside a predetermined tolerance, the capacitor or capacitor bank is flagged, during step 812.

In some embodiments, the predetermined tolerance is with 5% of the target capacitance value. Different tolerances may also be used. For example, in some embodiments, the predetermined tolerance is within 7.5% of the target capacitance value.

In some embodiments, the determined capacitance is compared with the target capacitance to determine whether the determined capacitance is outside the predetermined tolerance during step 810. In some embodiments, the determined capacitance is compared with a previous determined capacitance (determined during a previous step 810) to determine whether the determined capacitance is outside the predetermined tolerance during step 810.

In some embodiments, flagging the capacitor or capacitor bank during step 812 includes asserting a bit and/or signal. In some embodiments, flagging the capacitor or capacitor bank during step 812 includes alerting an operator (e.g., via a text, sound, etc.) that the capacitor or capacitor bank requires attention. In some embodiments, flagging the capacitor or capacitor bank during step 812 includes feeding information about the flagged capacitor (e.g., capacitance, aging information, and/or decreased ability for an AC filter to filter harmonics) to an operator terminal and/or into a maintenance management system of the FACTS.

During step 814, the capacitance of the capacitor or capacitor bank is determined or adjusted based on the new capacitance determined during step 808. For example, in some embodiments, a best fit polynomial approximation is generated based on capacitances values determined over time to determine or adjust the capacitance trend. The capacitance trend may be determined in other ways.

In some embodiments, the determination of the (e.g., long term, e.g., over weeks or months) capacitance trend of a capacitor or capacitor bank (e.g., during step 814) may involve using (e.g., linear) regression to find the best fit for the capacitance trend. For example, in some embodiments, the capacitance trend may be obtained by using

$$𝓎 = {γ}_{1} + {γ}_{2} x$$

$$[ \begin{matrix}{𝓎}_{1} \\ {𝓎}_{2} \\ … \\ {𝓎}_{n}\end{matrix} ] = [ \begin{matrix}1 & {x}_{1} & {x}_{1}^{2} & … & {x}_{1}^{m} \\ 1 & {x}_{2} & {x}_{2}^{2} & … & {x}_{2}^{m} \\ … & … & … & … & … \\ 1 & {x}_{n} & {x}_{n}^{2} & … & {x}_{n}^{m}\end{matrix} ] [ \begin{matrix}{γ}_{1} \\ {γ}_{2} \\ … \\ {γ}_{n}\end{matrix} ] , \qquad ( 10 )$$

$$[ γ ] = {{( {[ X ]}^{T} [ X ] )}^{- 1} [ X ]}^{T} [ Y ]$$

where y represents the sample data (e.g., capacitance values of the capacitor or capacitor bank over time), γ represents the unknown parameters to the regression, m represents the number of unknown parameters, and n represents the number of sampled data. As shown, Equation 10 uses a matrix form to find the best fit from linear to multi-degree regression.

In some embodiments, the outcome of the regression results in a single parameter γ₁ (also referred to as primary parameter) having a non-negligible value, while the other parameters (γ₂ to γₙ) (also referred to as secondary parameters) having negligible values (close to zero or zero), where γ₁ represents the capacitance. In some embodiments, the secondary parameters (γ₂ to γₙ) may increase over time as aging occurs. In some embodiments, as one or more of the secondary parameters increase, a projection of time to failure can be estimated, where the time of failure is the time when the projected capacitance falls outside the predetermined range, and the time to failure is the time it takes for such predicted failure to occur (e.g., based on the value of x that causes the projected capacitance to fall outside the predetermined range).

In some embodiments, the increase of one or more of the secondary parameters (γ₂ to γₙ) may be indicative of aging. In some embodiments, when one or more of the secondary parameters (γ₂ to γₙ) increases above a predetermined threshold, step 812 is performed.

In some embodiments, the determination of the capacitance trend of a capacitor or capacitor bank (e.g., during step 814) may involve using linear regression. In some embodiments, other regression methods may also be used.

If it is determined during step 816 that the capacitance trend is indicative of a capacitor failure, degradation or malfunction, step 812 is performed. For example, in some embodiments, if the capacitance trend indicates that the capacitance is expected to be outside the predetermined tolerance within a predetermined time period (e.g., within 3 month), step 812 is performed.

As another example, in some embodiments, if it is determined during step 816 that the determined capacitance is far from the prediction of the capacitance trend, e.g., such as when one or more of the primary or secondary parameters (γ₁ to γₙ) changes (even if it is within the predetermined tolerance of the target capacitance value), step 812 may be performed.

In some embodiments, flagging a capacitor or capacitor bank when the determined capacitance is far from the prediction of the capacitance trend may advantageously allow for detecting a cyber intrusion (which may cause spoofing of the measurement data).

As shown in FIG. 8, step 814 may be performed when the output of step 810 is “no.” In some embodiments, step 814 may also be performed when the output of step 810 is “yes.” By performing step 814 irrespective of the output of step 810, some embodiments advantageously continue to monitor the trend of the capacitance after the capacitor or capacitor is flagged, which may advantageously aid in adjusting the capacitance trend, e.g., to remove outliers and noise. Method 800 has been described with respect to an AC filter, such as 106. In some embodiments, method 800 may be implemented to monitor capacitors or capacitor banks in other circuits or devices, such as capacitor bank 118 of TSC circuit 102 (e.g., by measuring current I_{TSC} and voltage Vₗᵢₙₑ).

Method 800 illustrates the monitoring of the health of one capacitor or capacitor bank. In some embodiments, method 800 may be performed (e.g., simultaneously), for monitoring the health of a plurality of capacitors or capacitor banks. For example, in an embodiment in which SVC 400 includes 3 AC filters 106 (x=3), method 800 may be performed in parallel 4 times to monitor the health of the 3 capacitor banks 116 and the capacitor bank 118.

In some embodiments, method 800 may be performed in response to the capacitor or capacitor bank being flagged during step 508. In some embodiments, method 800 may be performed irrespective of whether the capacitor or capacitor bank has been flagged. In some embodiments, method 800 may be performed without performing methods 500 or 600.

As illustrated by FIG. 8, method 800 may be performed periodically. In some embodiments, method 800 may be performed on demand. In some embodiments, method 800 may be performed continuously. For example, in some embodiments, voltage and current samples are captured continuously (e.g., at 1 kHz or higher, such as at 1.2 kHz, e.g., during step 802), and the capacitance and capacitance trends are estimated in real time (during steps 808 and 814, respectively) as new samples are captured.

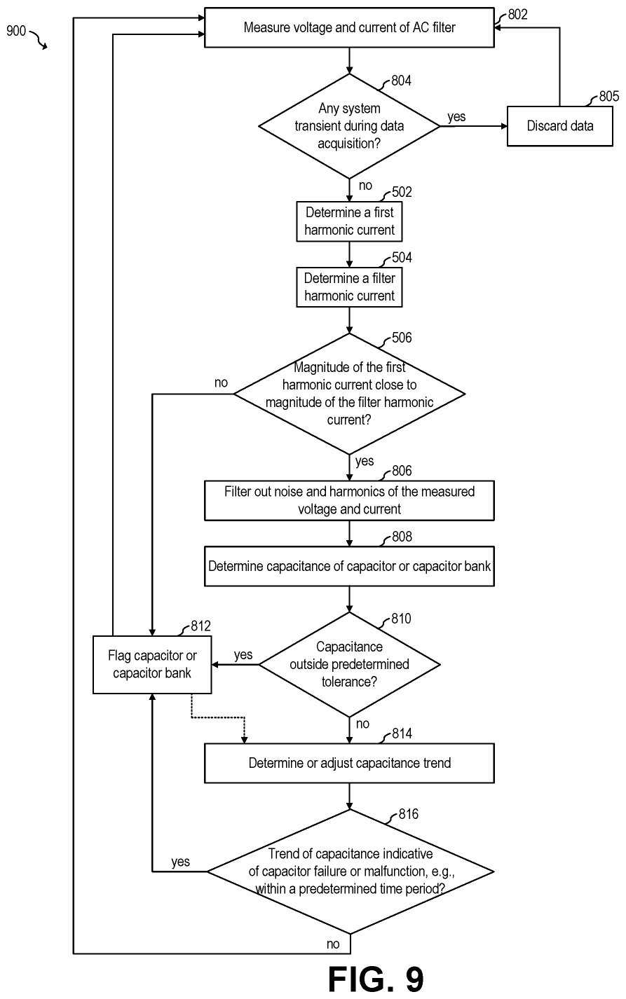

FIG. 9 shows a flow chart of embodiment method 900 for monitoring the health of a capacitor or capacitor bank, according to an embodiment of the present disclosure. Method 900 includes steps 502, 504, 506, 802, 804, 805, 806, 808, 810, 812, 814, and 816. Steps 502, 504, and 506 may be performed in a similar manner as described with respect to method 500. Steps 802, 804, 805, 806, 808, 810, 812, 814, and 816 may be performed in a similar manner as described with respect to method 800. In some embodiments, step 812 includes step 508. Method 900 may be implemented by, e.g., controller 402.

Method 900 is illustrative of a possible way of monitoring the health of a capacitor or capacitor bank. In some embodiments, one or more steps of method 900 may be omitted. For example, in some embodiments, steps 806, 808, 810, 814, and 816 may be omitted. In some embodiments, steps 814 and 816 may be omitted. In some embodiments, step 804 and 805 may be omitted. In some embodiments, steps 502, 504, 506, 814 and 816 may be omitted. In some embodiments, method 900 may be modified in other ways.

Method 900 illustrates the monitoring of the health of one capacitor or capacitor bank. In some embodiments, method 900 may be performed (e.g., simultaneously), for monitoring the health of a plurality of capacitors or capacitor banks.

In some embodiments, method 900 may be performed periodically. In some embodiments, method 900 may be performed on demand. In some embodiments, method 900 may be performed continuously.

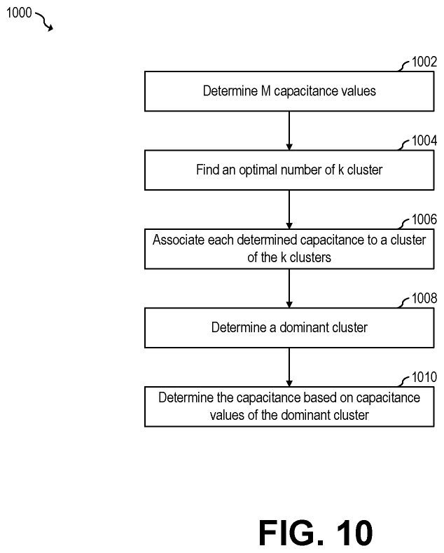

In some embodiments, the determination of the capacitance C_{det} across a capacitor or capacitor bank may be refined, e.g., using clustering. For example, in some embodiments, one or more determined capacitances C_{det} (e.g., determined during step 808) may include erroneous values due to the variation of the power system and/or noise from devices. In some embodiments, erroneous capacitance values are filtered out using statistical machine learning algorithm. For example, in some embodiments, a k-means clustering algorithm is used to remove erroneous capacitance values. For example, FIG. 10 shows a flow chart of embodiment method 1000 for determining a capacitance of a capacitor or capacitor bank, according to an embodiment of the present disclosure. In some embodiments, step 808 may be performed as method 1000.

During step 1002, M capacitance values are determined, e.g., based on the measurements collected during step 802, e.g., using one or more of Equations 6-9. In some embodiments, M is a positive integer greater than 10, such as 50 or 100.

During step 1004, an optimal number of k clusters is determined, where k is a positive integer greater than 1 and smaller than M. In some embodiments, k may be 2, 3, 4, 5, 6, 7, or higher. In some embodiments, the number of clusters k is determined by using minimum distances between data pairs (of the M capacitances values), iteratively. For example, in some embodiments, outlines are calculated for each cluster, and then the number k of clusters is selected so that there is minimum distance between datasets (clusters). In some embodiments, the number of clusters k may be pre-determined. In some embodiments, the number of clusters k may be determined during step 1002 (e.g., periodically). In some embodiments, the number of clusters k may be predetermined for real-time detection (e.g., for step 808) and may be dynamically determined for determining long-term trends (e.g., for step 814).

During step 1006, each of the capacitances determined during step 1002 is associated with a cluster (of the k clusters) having the nearest mean (e.g., using Euclidean distances), where the mean of a cluster is the mean of the capacitance values of the cluster.

After the M capacitance values are associated to a cluster, a dominant cluster is determined during step 1008 (and, e.g., discarding the capacitance values associated with the other clusters). For example, in some embodiments, the dominant cluster corresponds to the cluster (of the k clusters) having the largest count of capacitance values.

During step 1010, the capacitance value of the capacitor or capacitor bank is determined based on the capacitance values of the dominant cluster. For example, in some embodiments, the capacitance value of the capacitor or capacitor bank is determined as the median of the capacitance values of the dominant cluster. As another example, in some embodiments, the capacitance value of the capacitor or capacitor bank is determined as the average of the capacitance values of the dominant cluster.

In some embodiments, the dominant cluster advantageously includes a small number of high-quality capacitance values (e.g., that are free from outliers), thereby advantageously allowing for the determination of a more accurate capacitance value compared to using all of the M capacitance values.

In some embodiments, method 1000 may be performed periodically. In some embodiments, method 1000 may be performed continuously. In some embodiments, method 1000 may be performed on demand.

In some embodiments, during step 808, method 1000 may be performed to determine (e.g., real time) the capacitance value of a capacitor or capacitor bank. In some embodiments, during step 814, method 1000 may be performed to determine the capacitance values to be used in determining the capacitance trend of a capacitor or capacitor bank.

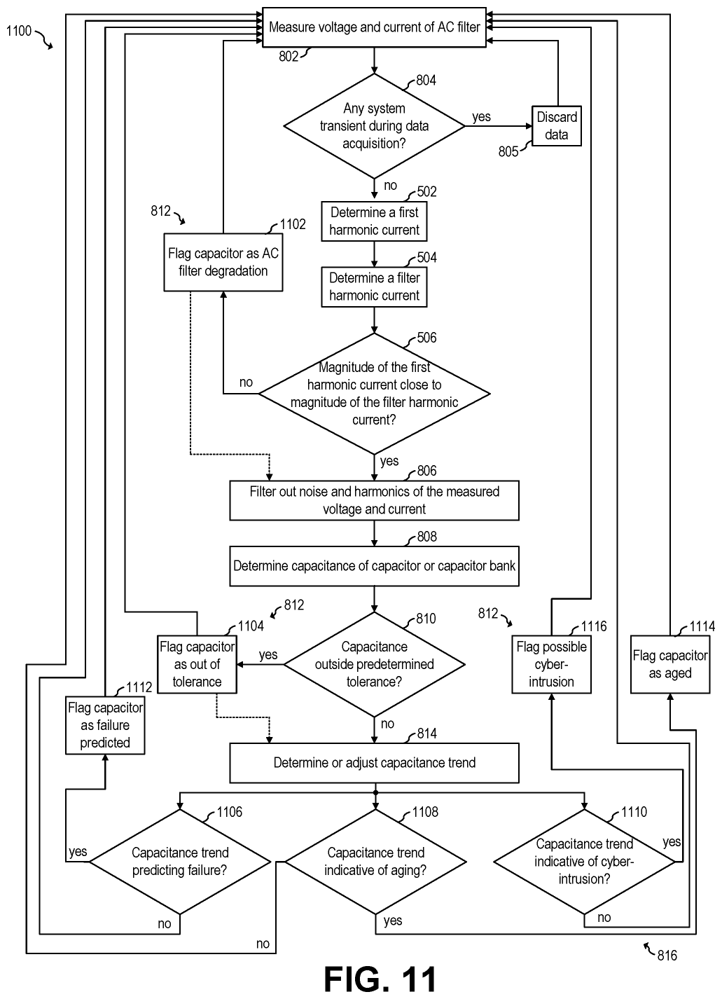

FIG. 11 shows a flow chart of embodiment method 1100 for monitoring the health of a capacitor or capacitor bank, according to an embodiment of the present disclosure. Method 1100 illustrates a possible implementation of method 900 where step 812 includes steps 1102, 1104, 1112, 1114, and 1116, and step 816 includes steps 1106, 1108, and 1110. Method 1100 may be implemented by, e.g., controller 402.

As shown in FIG. 11, when the capacitance is determined to be outside the predetermined tolerance during step 810, the capacitor or capacitor bank is flagged as being out of tolerance during step 1104. In some embodiments, once the capacitor or capacitor bank is flagged during step 1104, step 814 is performed. In some embodiments, once the capacitor or capacitor bank is flagged during step 1104, step 802 is performed. In some embodiments, once the capacitor or capacitor bank is flagged during step 1104, method 1100 stops.

As shown in FIG. 11, during step 816, steps 1106, 1108 and 1110 are performed (e.g., simultaneously or sequentially). If it is determined during step 1106 that the capacitance trend is indicative of capacitor failure within a predetermined time period (e.g., the estimated capacitance at a predetermined future time being lower than a predetermined threshold), the capacitor or capacitor bank is flagged during step 1112 as failure predicted for such capacitor or capacitor bank. In some embodiments, time of failure is predicted during step 1106 by extrapolating using the outcome of the regression (e.g., using Equation 10, and determining the value of x for which the capacitance falls out of tolerance, where variable x corresponds to a time domain that can be used to determine a time in which the capacitance falls out of tolerance). In some embodiments, one or more of the secondary parameters (γ₂ to γₙ) may be used for estimating time of failure. If it is determined during step 1108 that the capacitance trend is indicative of aging of the capacitor or capacitor bank, the capacitor or capacitor bank is flagged during step 1114 as aged. In some embodiments, step 1108 outputs “yes” when one or more of the secondary parameters (γ₂ to γₙ) increases above a predetermined threshold.

If it is determined during step 1110 that the capacitance trend is indicative of a possible cyber intrusion, a flag is issued to signal that a possible cyber intrusion has occurred. In some embodiments, a possible cyber intrusion is detected when the capacitance trend deviates from previous capacitance trend estimates. For example, in some embodiments, a possible cyber intrusion is detected if any of the primary or secondary parameters of the regression (γ₁ to γₙ) changes more than a predetermined threshold compared to the previous estimate of such parameter. In some embodiments, the predetermined threshold may be the same for all the primary and secondary parameters. In some embodiments, one or more (or all) of the predetermined thresholds may be different.

In some embodiments, method 1100 may be performed periodically. In some embodiments, method 1100 may be performed continuously. In some embodiments, method 1100 may be performed on demand.

In some embodiments, methods 500, 600, 800, 900, 1000, and/or 1100 may be implemented by controller 402 to monitor the health of capacitors or capacitor banks in an SVC (e.g., SVC 400). In some embodiments, methods 500, 600, 800, 900, 1000, and/or 1100 may be used to monitor the health of capacitor or capacitor banks in other devices or circuits, such as STATCOM or HVDC systems.

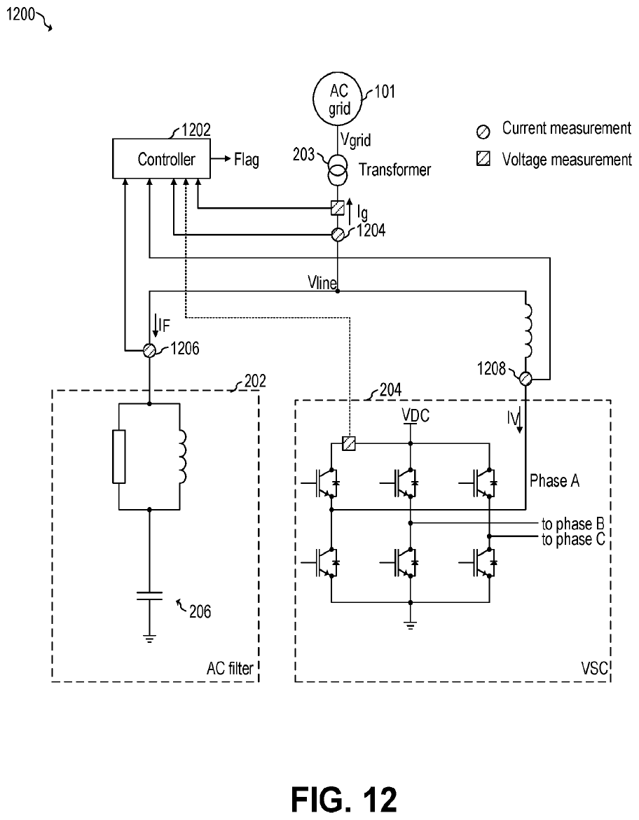

FIG. 12 shows a schematic diagram of STATCOM 1200, according to an embodiment of the present disclosure. STATCOM 1200 operates in a similar manner as STATCOM 200.

STATCOM 1200, however, includes controller 1202. In some embodiments, controller 1202 is part of an IED.

In some embodiments, STATCOM 1200 may include a plurality of AC filters 202. For example, in some embodiments, STATCOM 1200 may include x AC filters 202, e.g., for filtering respective harmonics, where x is a positive integer greater than or equal to 1.

In some embodiments, current measurement circuits 1204, 1206, and 1208 may be implemented in any way known in the art, e.g., in a manner similar or identical to current measurements circuits 406, 408, 410, and/or 412. In some embodiments having a plurality of AC filters 202, each AC filter 202 may have a corresponding current measurement circuit 1206. In some embodiments having a plurality of AC filters 202, a single current measurement circuit 1206 may be shared across the plurality of AC filters 202.

In some embodiments, controller 1202 includes one or more input terminals configured to receive data from current measurement circuits 1204, 1206, and 1208 and perform further processing based on the received data. In some embodiments, controller 1202 may be implemented as a custom or generic controller or processor, e.g., coupled to a memory and configured to execute instructions stored in the memory.

In some embodiments having a plurality of AC filters 202, each of the AC filters 202 is designed to filter a respective harmonic. For example, in some embodiments, STATCOM 1200 includes 3 AC filters 202 designed to filter the higher 39^{th} to more harmonic, respectively. Other target harmonics (e.g., depending on the design of the STATCOM) may be used.

In some embodiments, one or more (or all) of AC filters 202 may be implemented with the topology shown in FIG. 12. In some embodiments, one or more (or all) of AC filters 202 may be implemented with a different topology. In some embodiments, one or more (or all) of AC filters 202 may be implemented as high pass filter or band pass filter. In some embodiments, one or more (or all) of AC filters 202 may be implemented as a double tuned filter. In some embodiments, one or more (or all) of AC filters 202 may be implemented as a shunt capacitor. In some embodiments, one or more (or all) of AC filters 202 may be implemented as AC filters 700 or 720 (shown in FIGS. 7A and 7B, respectively). Other implementations are also possible.

According to KCL, in some embodiments, the relationship between harmonic currents I_{g}ⁿ^{^{th}}, I_{V}ⁿ^{^{th}}, and I_{F}ⁿ^{^{th}} may be given by

$${I}_{g}^{{n}^{th}} + {I}_{V}^{{n}^{th}} + {I}_{F}^{{n}^{th}} = 0 , \qquad ( 11 )$$

where I_{g}ⁿ^{^{th}} represents the n^{th} harmonic current going into AC grid 101, I_{F}ⁿ^{^{th}} represents the n^{th} harmonic current going into AC filter 202, and I_{V}ⁿ^{^{th}} represents the n^{th} harmonic current going into VSC circuit 204.

In some embodiments, the n^{th} harmonic current may be determined by measuring the current (e.g., I_{F}, I_{V}, and I_{g}, e.g., in a known manner), performing a Fourier transform (e.g., a DFT) on the measured current to generate a frequency spectrum, and determine the energy at the frequency corresponding to the n^{th} harmonic in the generated frequency spectrum.

In some embodiments, n is equal to 5, 7, 13, or 39. In some embodiments, n may be a different number, such as a different odd number.

It can be inferred from Equation 11 that, for the n^{th} harmonic current I_{g}ⁿ^{^{th}} going into AC grid 101 to be zero, then

$${I}_{F}^{{n}^{th}} = - {I}_{V}^{{n}^{th}} . \qquad ( 12 )$$

As can be seen, Equation 12 is similar to Equation 4, but replaces the term I_{TCR}ⁿ^{^{th}} with I_{V}ⁿ^{^{th}}. In some embodiments, Equation 5 may be modified in view of Equation 12 as

$$\frac{{I}_{F}^{{n}^{th}} - {I}_{V}^{{n}^{th}}}{{I}_{V}^{{n}^{th}}} < {I}_{thres}^{{n}^{th}} . \qquad ( 13 )$$

to apply to STATCOM 1200. Thus, in some embodiments, controller 1202 may implement methods 500, 600, 800, 900, 1000, and/or 1100 by implementing step 506 using I_{V}ⁿ^{^{th}} instead of I_{TCR}ⁿ^{^{th}} (e.g., using Equation 13 instead of Equation 5).

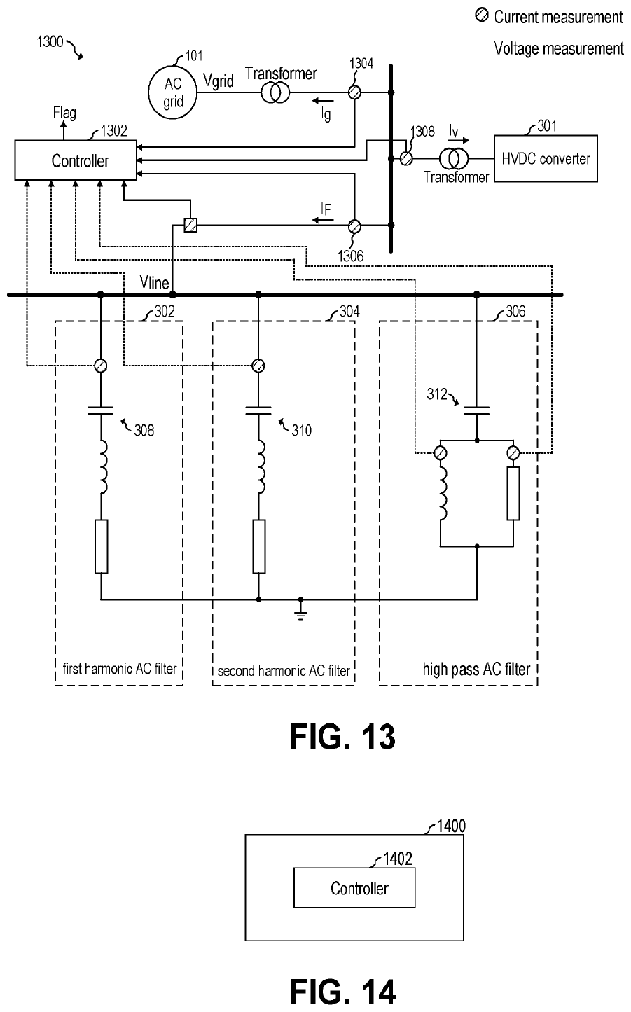

FIG. 13 shows a schematic diagram of HVDC system 1300, according to an embodiment of the present disclosure. HVDC system 1300 operates in a similar manner as HVDC system 300.

HVDC system 1300, however, includes controller 1302. In some embodiments, controller 1302 is part of an IED.

In some embodiments, HVDC system 1300 may include a plurality of AC filters. For example, as shown in FIG. 13, HVDC system 1300 may include 3 AC filters 302, 304, and 306.

In some embodiments, current measurement circuits 1304, 1306, and 1308 may be implemented in any way known in the art, e.g., in a manner similar or identical to current measurements circuits 406, 408, 410, and/or 412.

In some embodiments, controller 1302 includes one or more input terminals configured to receive data from current measurement circuits 1304, 1306, and 1308 and perform further processing based on the received data. In some embodiments, controller 1302 may be implemented as a custom or generic controller or processor, e.g., coupled to a memory and configured to execute instructions stored in the memory.

In some embodiments AC filters 302 and 304 are designed to filter the 11^{th} and 13^{th} harmonic, respectively. In some embodiments, AC filters 302 and 304 may be designed to filter other harmonics, such as other odd harmonics of the fundamental frequency (e.g., 60 Hz or 50 Hz) respective harmonic.

In some embodiments, one or more (or all) of AC filters 302, 304, and 306 may be implemented with the respective topologies shown in FIG. 13. In some embodiments, one or more (or all) of AC filters 302, 304, and 306 may be implemented with a different topology. In some embodiments, one or more (or all) of AC filters 302, 304, and 306 may be implemented as high pass filter or band pass filter. In some embodiments, one or more (or all) of AC filters 302, 304, and 306 may be implemented as a double tuned filter. In some embodiments, one or more (or all) of AC filters 302, 304, and 306 may be implemented as a shunt capacitor. In some embodiments, one or more (or all) of AC filters 302, 304, and 306 may be implemented as AC filters 700 or 720 (shown in FIGS. 7A and 7B, respectively). Other implementations are also possible.

According to KCL, in some embodiments, the relationship between harmonic currents I_{g}ⁿ^{^{th}}, Iᵥⁿ^{^{th}}, and I_{F}ⁿ^{^{th}} may be given by

$${I}_{g}^{{n}^{th}} + {I}_{v}^{{n}^{th}} + {I}_{F}^{{n}^{th}} = 0 , \qquad ( 14 )$$

where I_{g}ⁿ^{^{th}} represents the n^{th} harmonic current going into AC grid 101, I_{F}ⁿ^{^{th}} represents the n^{th} harmonic current going into AC filter 202, and Iᵥⁿ^{^{th}} represents the n^{th} harmonic current going into AC filters 302, 304, and 306.

In some embodiments, the n^{th} harmonic current may be determined by measuring the current (e.g., I_{F}, I_{V}, and I_{g}, e.g., in a known manner), performing a Fourier transform (e.g., a DFT) on the measured current to generate a frequency spectrum, and determine the energy at the frequency corresponding to the n^{th} harmonic in the generated frequency spectrum.

In some embodiments, n is equal to 11, and 13. In some embodiments, n may be a different number, such as a different odd number.

It can be inferred from Equation 11 that, for the n^{th} harmonic current I_{g}ⁿ^{^{th}} going into AC grid 101 to be zero, then

$${I}_{F}^{{n}^{th}} = - {I}_{v}^{{n}^{th}} . \qquad ( 15 )$$

As can be seen, Equation 15 is similar to Equation 4, but replaces the term I_{TCR}ⁿ^{^{th}} with Iᵥⁿ^{^{th}}. In some embodiments, Equation 5 may be modified in view of Equation 15 as

$$\frac{{I}_{F}^{{n}^{th}} - {I}_{v}^{{n}^{th}}}{{I}_{v}^{{n}^{th}}} < {I}_{thres}^{{n}^{th}} . \qquad ( 16 )$$

to apply to HVDC system 1300. Thus, in some embodiments, controller 1302 may implement methods 500, 600, 800, 900, 1000, and/or 1100 by implementing step 506 using Iᵥⁿ^{^{th}} instead of I_{TCR}ⁿ^{^{th}} (e.g., using Equation 16 instead of Equation 5).

FIG. 14 shows a schematic diagram of device 1400, according to an embodiment of the present disclosure. Device 1400 includes controller 1402. In some embodiments, controller 1402 may be implemented as controller 402, 1202 or 1302.

In some embodiments, device 1400 is an IED. In some embodiments, device 1400 is a remote server that receives data (e.g., I_{F}, I_{TSC}, I_{TCR}, I_{V}, Iᵥ, Vₗᵢₙₑ, etc.) from an IED.

Example embodiments of the present disclosure are summarized here. Other embodiments can also be understood from the entirety of the specification and the claims filed herein.

Example 1. An electronic circuit including: one or more input terminals configured to receive measurement data; and a controller configured to: determine a first harmonic current based on a first current flowing through a first circuit coupled to a line node, where the measurement data includes first current data indicative of the first current, determine a filter harmonic current based on a filter current flowing through an AC filter coupled to the line node, where the measurement data includes filter current data indicative of the filter current, and generate a first flag indicative of failure, degradation or malfunction of a first capacitor or capacitor bank based on the first harmonic current and the filter harmonic current, where the AC filter includes the first capacitor or capacitor bank.

Example 2. The electronic circuit of example 1, where the controller is configured to generate the first flag when the filter harmonic current within a predetermined tolerance of the first harmonic current.

Example 3. The electronic circuit of one of examples 1 or 2, where the controller is configured to generate the first flag when

$$\frac{{I}_{F}^{{n}^{th}} - {I}_{1 st}^{{n}^{th}}}{{I}_{1 st}^{{n}^{th}}} < {I}_{thres}^{{n}^{th}} ,$$

where I_{F}ⁿ^{^{th}} represents the filter harmonic current, where I₁ₛₜⁿ^{^{th}} represents the first circuit harmonic current, and where Iₜₕᵣₑₛⁿ^{^{th}} is higher than 90%.

Example 4. The electronic circuit of one of examples 1 to 3, where the AC filter is designed to filter an n^{th} harmonic of a fundamental frequency, where the first harmonic current corresponds to the nth harmonic of the fundamental frequency, where the filter harmonic current corresponds to the nth harmonic of a fundamental frequency, and where generating the first flag includes identifying the first capacitor or capacitor bank of the AC filter designed to filter the nth harmonic of the fundamental frequency as the failed, degraded or malfunctioned capacitor or capacitor bank.

Example 5. The electronic circuit of one of examples 1 to 4, where n is equal to 5, 7, 11, 13, or 39.

Example 6. The electronic circuit of one of examples 1 to 5, where the controller is configured to continuously determine the first harmonic current and the filter harmonic current.

Example 7. The electronic circuit of one of examples 1 to 6, where the controller is further configured to determine a first capacitance of the first capacitor or capacitor bank, compare the first capacitance with a reference capacitance, and generate a second flag when the first capacitance differs from the reference capacitance by more than a predetermined tolerance, where the second flag is indicative of a failure, degradation, or malfunction of the first capacitor or capacitor bank.

Example 8. The electronic circuit of one of examples 1 to 7, where the controller is configured to determine the first capacitance in response to the first flag.

Example 9. The electronic circuit of one of examples 1 to 8, where the reference capacitance is a target capacitance of the first capacitor or capacitor bank.

Example 10. The electronic circuit of one of examples 1 to 9, where the reference capacitance corresponds to a previously measured capacitance of the first capacitor or capacitor bank.

Example 11. The electronic circuit of one of examples 1 to 10, where the controller is configured to determine the first capacitance by: determining M capacitance values of the first capacitor or capacitor bank, where M is a positive integer greater than 1; associating each of the M determined capacitance values to a cluster of k clusters, where k is a positive integer greater than 1 and smaller than M; determining a dominant cluster from the k clusters; and determining the first capacitance based on the capacitance values of the dominant cluster.

Example 12. The electronic circuit of one of examples 1 to 11, where the controller is configured to associate each of the M determined capacitances values to a cluster of the k clusters having a nearest mean.

Example 13. The electronic circuit of one of examples 1 to 12, where the controller is configured to determine the dominant cluster as the cluster having the highest count of capacitance values.

Example 14. The electronic circuit of one of examples 1 to 13, where the controller is further configured to: determine or adjust a capacitance trend of the first capacitor or capacitor bank based on the first capacitance; and generate a third flag when the capacitance trend is indicative of a failure, degradation, or malfunction associated with the first capacitor or capacitor bank.

Example 15. The electronic circuit of one of examples 1 to 14, where the controller is configured to generate the third flag when the capacitance trend is indicative of the first capacitance falling out of tolerance within a predetermined time period.

Example 16. The electronic circuit of one of examples 1 to 15, where the controller is configured to determine or adjust the capacitance trend using linear regression.

Example 17. The electronic circuit of one of examples 1 to 16, where the controller is configured to generate the third flag when a primary or secondary parameter of the capacitance trend increases above a predetermined threshold.

Example 18. The electronic circuit of one of examples 1 to 17, where the controller is configured to detect a cyber intrusion when a primary or secondary parameter of the capacitance trend increases above a predetermined threshold.

Example 19. The electronic circuit of one of examples 1 to 18, where the first circuit is a thyristor-controlled reactor (TCR) circuit, a voltage-source converter (VSC), or a high-voltage direct current (HVDC) converter.

Example 20. The electronic circuit of one of examples 1 to 19, where the controller is configured to: determine the first harmonic current by performing a Fourier transform on the first current data; and determine the filter harmonic current by performing a Fourier transform on the filter current data.

Example 21. A method including: determining a first harmonic current based on a first current flowing through a first circuit coupled to a line node; determining a filter harmonic current based on a filter current flowing through an AC filter coupled to the line node; and generating a first flag indicative of failure, degradation or malfunction of a first capacitor or capacitor bank based on the first harmonic current and the filter harmonic current, where the AC filter includes the first capacitor or capacitor bank.

Example 22. The method of example 21, further including: determining a first capacitance of the first capacitor or capacitor bank; comparing the first capacitance with a reference capacitance; and generating a second flag when the first capacitance differs from the reference capacitance by more than a predetermined tolerance, where the second flag is indicative of a failure, degradation, or malfunction of the first capacitor or capacitor bank.

Example 23. The method of one of examples 21 or 22, where determining the first capacitance includes determining the first capacitance continuously.

Example 24. The method of one of examples 21 to 23, where determining the first capacitance includes: determining M capacitance values of the first capacitor or capacitor bank, where M is a positive integer greater than 1; associating each of the M determined capacitance values to a cluster of k clusters, where k is a positive integer greater than 1 and smaller than M; determining a dominant cluster from the k clusters; and determining the first capacitance based on the capacitance values of the dominant cluster.

Example 25. The method of one of examples 21 to 24, further including: determining or adjusting a capacitance trend of the first capacitor or capacitor bank based on the first capacitance using linear regression; and generating a third flag when the capacitance trend is indicative of a failure, degradation, or malfunction associated with the first capacitor or capacitor bank.

Example 26. A device including: one or more input terminals configured to receive measurement data; and a controller configured to: determine M capacitance values of a first capacitor or capacitor bank of an AC filter coupled to a line node based on the measurement data, where M is a positive integer greater than 1, associate each of the M determined capacitance values to a cluster of k clusters, where k is a positive integer greater than 1 and smaller than M, determine a dominant cluster from the k clusters, determine a first capacitance based on the capacitance values of the dominant cluster, compare the first capacitance with a reference capacitance, and generate a first flag when the first capacitance differs from the reference capacitance by more than a predetermined tolerance, where the first flag is indicative of a failure, degradation, or malfunction of the first capacitor or capacitor bank.

Example 27. The device of example 26, where the controller is further configured to: determine a first harmonic current based on a first current flowing through a first circuit coupled to the line node, where the measurement data includes first current data indicative of the first current; determine a filter harmonic current based on a filter current flowing through the AC filter, where the measurement data includes filter current data indicative of the filter current; and generate a second flag indicative of failure, degradation or malfunction of a first capacitor or capacitor bank based on the first harmonic current and the filter harmonic current, where the controller is configured to determine the M capacitance values in response to the second flag.

Example 28. The device of one of examples 26 or 27, where the device is an intelligent electronic device (IED).

Example 29. The device of one of examples 26 to 28, where the device is a server.

While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

1. An electronic circuit comprising:
one or more input terminals configured to receive measurement data; and
a controller configured to:
determine a first harmonic current based on a first current flowing through a first circuit coupled to a line node, wherein the measurement data comprises first current data indicative of the first current,
determine a filter harmonic current based on a filter current flowing through an AC filter coupled to the line node, wherein the measurement data comprises filter current data indicative of the filter current, and
generate a first flag indicative of failure, degradation, or malfunction of a first capacitor or capacitor bank based on the first harmonic current and the filter harmonic current, wherein the AC filter comprises the first capacitor or capacitor bank.

2. The electronic circuit of claim 1, wherein the controller is configured to generate the first flag when the filter harmonic current is within a predetermined tolerance of the first harmonic current.

3. The electronic circuit of claim 1, wherein the controller is configured to generate the first flag when
$$\frac{{I}_{F}^{{n}^{th}} - {I}_{1 st}^{{n}^{th}}}{{I}_{1 st}^{{n}^{th}}} < {I}_{thres}^{{n}^{th}} ,$$
wherein I_{F}ⁿ^{^{th}} represents the filter harmonic current, wherein I₁ₛₜⁿ^{^{th}} represents the first circuit harmonic current, and wherein Iₜₕᵣₑₛⁿ^{^{th}} is higher than 90%.

4. The electronic circuit of claim 1, wherein the AC filter is designed to filter an n^{th} harmonic of a fundamental frequency, wherein the first harmonic current corresponds to the n^{th} harmonic of the fundamental frequency, wherein the filter harmonic current corresponds to the n^{th} harmonic of a fundamental frequency, and wherein generating the first flag comprises identifying the first capacitor or capacitor bank of the AC filter designed to filter the n^{th} harmonic of the fundamental frequency as the failed, degraded, or malfunctioned capacitor or capacitor bank.

5. The electronic circuit of claim 4, wherein n is equal to 5, 7, 11, 13, or 39.

6. The electronic circuit of claim 1, wherein the controller is configured to continuously determine the first harmonic current and the filter harmonic current.

7. The electronic circuit of claim 6, wherein the controller is further configured to determine a first capacitance of the first capacitor or capacitor bank, compare the first capacitance with a reference capacitance, and generate a second flag when the first capacitance differs from the reference capacitance by more than a predetermined tolerance, wherein the second flag is indicative of a failure, degradation, or malfunction of the first capacitor or capacitor bank.

8. The electronic circuit of claim 7, wherein the controller is configured to determine the first capacitance in response to the first flag.

9. The electronic circuit of claim 7, wherein the reference capacitance is a target capacitance of the first capacitor or capacitor bank.

10. The electronic circuit of claim 7, wherein the reference capacitance corresponds to a previously measured capacitance of the first capacitor or capacitor bank.

11. The electronic circuit of claim 7, wherein the controller is configured to determine the first capacitance by:
determining M capacitance values of the first capacitor or capacitor bank, wherein M is a positive integer greater than 1;
associating each of the M determined capacitance values to a cluster of k clusters, wherein k is a positive integer greater than 1 and smaller than M;
determining a dominant cluster from the k clusters; and
determining the first capacitance based on the capacitance values of the dominant cluster.

12. The electronic circuit of claim 11, wherein the controller is configured to associate each of the M determined capacitances values to a cluster of the k clusters having a nearest mean.

13. The electronic circuit of claim 11, wherein the controller is configured to determine the dominant cluster as the cluster having the highest count of capacitance values.

14. The electronic circuit of claim 7, wherein the controller is further configured to:
determine or adjust a capacitance trend of the first capacitor or capacitor bank based on the first capacitance; and
generate a third flag when the capacitance trend is indicative of a failure, degradation, or malfunction associated with the first capacitor or capacitor bank.

15. The electronic circuit of claim 14, wherein the controller is configured to generate the third flag when the capacitance trend is indicative of the first capacitance falling out of tolerance within a predetermined time period.

16. The electronic circuit of claim 14, wherein the controller is configured to determine or adjust the capacitance trend using linear regression.

17. The electronic circuit of claim 16, wherein the controller is configured to generate the third flag when a primary or secondary parameter of the capacitance trend increases above a predetermined threshold.

18. The electronic circuit of claim 16, wherein the controller is configured to detect a cyber intrusion when a primary or secondary parameter of the capacitance trend increases above a predetermined threshold.

19. The electronic circuit of claim 1, wherein the first circuit is a thyristor-controlled reactor (TCR) circuit, a voltage-source converter (VSC), or a high-voltage direct current (HVDC) converter.

20. The electronic circuit of claim 1, wherein the controller is configured to:
determine the first harmonic current by performing a Fourier transform on the first current data; and
determine the filter harmonic current by performing a Fourier transform on the filter current data.

21. A method comprising:
determining a first harmonic current based on a first current flowing through a first circuit coupled to a line node;
determining a filter harmonic current based on a filter current flowing through an AC filter coupled to the line node; and
generating a first flag indicative of failure, degradation, or malfunction of a first capacitor or capacitor bank based on the first harmonic current and the filter harmonic current, wherein the AC filter comprises the first capacitor or capacitor bank.

22. The method of claim 21, further comprising:
determining a first capacitance of the first capacitor or capacitor bank;
comparing the first capacitance with a reference capacitance; and
generating a second flag when the first capacitance differs from the reference capacitance by more than a predetermined tolerance, wherein the second flag is indicative of a failure, degradation, or malfunction of the first capacitor or capacitor bank.

23. The method of claim 22, wherein determining the first capacitance comprises determining the first capacitance continuously.

24. The method of claim 22, wherein determining the first capacitance comprises:
determining M capacitance values of the first capacitor or capacitor bank, wherein M is a positive integer greater than 1;
associating each of the M determined capacitance values to a cluster of k clusters, wherein k is a positive integer greater than 1 and smaller than M;
determining a dominant cluster from the k clusters; and
determining the first capacitance based on the capacitance values of the dominant cluster.

25. The method of claim 22, further comprising:
determining or adjusting a capacitance trend of the first capacitor or capacitor bank based on the first capacitance using linear regression; and
generating a third flag when the capacitance trend is indicative of a failure, degradation, or malfunction associated with the first capacitor or capacitor bank.

26. A device comprising:
one or more input terminals configured to receive measurement data; and
a controller configured to:
determine M capacitance values of a first capacitor or capacitor bank of an AC filter coupled to a line node based on the measurement data, wherein M is a positive integer greater than 1,
associate each of the M determined capacitance values to a cluster of k clusters, wherein k is a positive integer greater than 1 and smaller than M,
determine a dominant cluster from the k clusters,
determine a first capacitance based on the capacitance values of the dominant cluster,
compare the first capacitance with a reference capacitance, and
generate a first flag when the first capacitance differs from the reference capacitance by more than a predetermined tolerance, wherein the first flag is indicative of a failure, degradation, or malfunction of the first capacitor or capacitor bank.

27. The device of claim 26, wherein the controller is further configured to:
determine a first harmonic current based on a first current flowing through a first circuit coupled to the line node, wherein the measurement data comprises first current data indicative of the first current;
determine a filter harmonic current based on a filter current flowing through the AC filter, wherein the measurement data comprises filter current data indicative of the filter current; and
generate a second flag indicative of failure, degradation, or malfunction of a first capacitor or capacitor bank based on the first harmonic current and the filter harmonic current, wherein the controller is configured to determine the M capacitance values in response to the second flag.

28. The device of claim 26, wherein the device is an intelligent electronic device (IED).

29. The device of claim 26, wherein the device is a server.
